(19) United States
(12) Patent Application Publication
(10) Pub. No.: US 2011/0227583 A1
(43) Pub. Date: Sep. 22, 2011

(54) TEST SYSTEM

(75) Inventors: YUNG-CHENG HUNG, Tu-Cheng (TW); WANG-DING SU, Tu-Cheng (TW); JUI-HSIUNG HO, Tu-Cheng (TW)

(73) Assignee: HON HAI PRECISION INDUSTRY CO., LTD., Tu-Cheng (TW)

(21) Appl. No.: 12/764,968

(22) Filed: Apr. 22, 2010

(30) Foreign Application Priority Data
Mar. 16, 2010 (CN) 201010126233.8

(51) Int. Cl. G01R 31/04

(52) U.S. Cl. 324/538

(57) ABSTRACT

A test system includes a serial advanced technology attachment (SATA) test apparatus, a number of test cables, and an oscillograph. Each test cable includes a soft sub-miniature-a wire and a sub-miniature-a connector. A first terminal of each sub-miniature-a wire is electrically fixed to an output of the SATA test apparatus. A second terminal of each sub-miniature-a wire is connected to the corresponding sub-miniature-a connector. Each sub-miniature-a connector is used to connect to an input of the oscillograph.

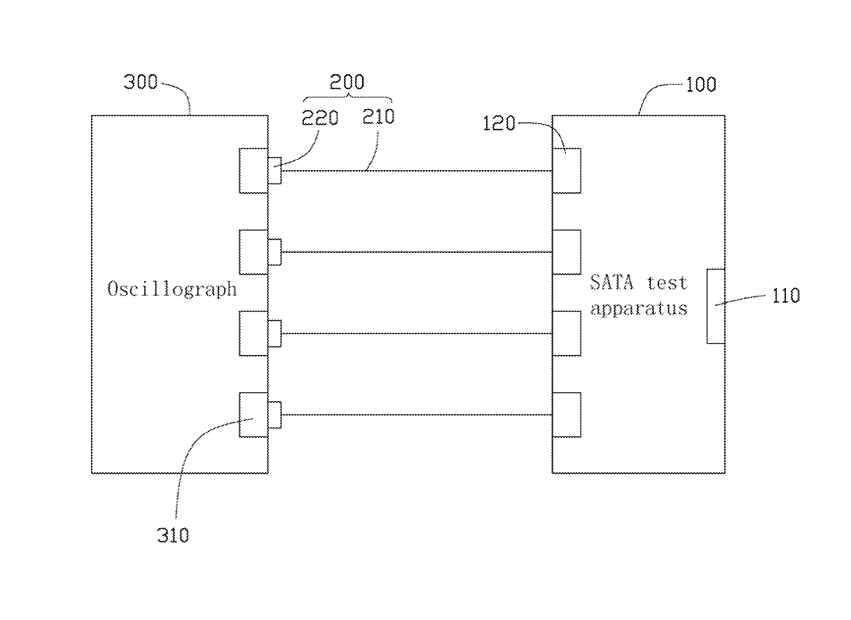

### BACKGROUND

1. Technical Field

The present disclosure relates to a test system.

2. Description of Related Art

Serial advanced technology attachment (SATA) is a standard based on serial signaling technology for connecting mass storage devices to computer systems. There are some SATA test apparatuses for testing SATA connectors of the mass storage device, such as a COMAX/H303000202-G-0275 type of SATA test apparatus. However, adapters must be used to correctly connect the SATA connectors to the test equipment and this introduces noise and decrease the strength of the test signals. Additionally, hard coaxial cable are also used in the test and if the hard coaxial cable should be bent, cracking of the cable may occur, which would effect test results.

### BRIEF DESCRIPTION OF THE DRAWING

The drawing is a schematic view of an embodiment of a test system.

### DETAILED DESCRIPTION

Referring to the drawing, an embodiment of a test system includes a serial advanced technology attachment (SATA) test apparatus 100, four test cables 200, and an oscillograph 300. The test system is used to test a SATA connector of a hard disk.

The SATA test apparatus 100 is a COMAX/H303000202-G-0275, and includes a first input 110 and four first outputs 120. One end of the SATA connector is connected to the hard drive and the other end of the SATA connector is connected to the first input 110 of the SATA test apparatus 100.

Each of the test cables 200 includes a soft sub-miniature-a wire 210 and a sub-miniature-a male connector 220.

A first terminal of each sub-miniature-a wire 210 is electrically fixed to a corresponding first output 120 of the SATA test apparatus 100. A second terminal of each sub-miniature-a wire 210 is attached to the sub-miniature-a male connector 220.

The oscillograph 300 includes four second inputs 310. Each second input 310 is a sub-miniature-a female connector. Each sub-miniature-a male connector 220 is correspondingly connected to a second input 310 of the oscillograph 300.

In use, the four first outputs 120 of the SATA test apparatus 100 transmit signals of the SATA connector to the four sub-miniature-a wires 210. Each signal of the SATA connector is transmitted to the oscillograph 300 via a sub-miniature-a male connector 220 connected to a second input 310 of the oscillograph 300. A determination can be made whether the SATA connector is working well by observing waveforms of the signals shown on the oscillograph 300.

The foregoing description of the exemplary embodiments of the disclosure has been presented only for the purposes of illustration and description and is not intended to be exhaustive or to limit the disclosure to the precise forms disclosed. Many modifications and variations are possible in light of the above. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A test system for a serial advanced technology attachment (SATA) connector, the test system comprising:
a SATA test apparatus comprising a first input to be connected to the SATA connector, and a plurality of outputs;
a plurality of test cables each comprising a soft sub-miniature-a wire and a sub-miniature-a connector, wherein a first terminal of each sub-miniature-a wire is electrically fixed to a corresponding output of the SATA test apparatus, a second terminal of each sub-miniature-a wire is connected to the corresponding sub-miniature-a connector; and
an oscillograph comprising a plurality of second inputs, wherein each second input is connected to the sub-miniature-a connector of a corresponding test cable.

2. The test system of claim 1, wherein the type of the SATA test apparatus is COMAX/H303000202-G-0275.

3. The test system of claim 1, wherein the sub-miniature-a connector of each test cable is a sub-miniature-a male connector.

4. The test system of claim 1, wherein the plurality of second inputs of the oscillograph are sub-miniature-a female connectors.
